(19) United States
(12) Patent Application Publication
(10) Pub. No.: US 2017/0141076 A1
(43) Pub. Date: May 18, 2017

(54) LIGHT EMITTING DEVICE

(71) Applicant: PANASONIC INTELLECTUAL PROPERTY MANAGEMENT CO., LTD., Osaka (JP)

(72) Inventor: Norihiro ITO, Osaka (JP)

(73) Assignee: PANASONIC INTELLECTUAL PROPERTY MANAGEMENT CO., LTD., Osaka (JP)

(21) Appl. No.: 15/318,503

(22) PCT Filed: Jul. 1, 2015
(86) PCT No.: PCT/JP2015/003306

§ 371 Date: Dec. 13, 2016

(30) Foreign Application Priority Data
Jul. 23, 2014 (JP) 2014-149500

(51) Int. Cl. H01L 25/04; H01L 51/52; H01L 51/00; F21S 2/00

(52) U.S. Cl. CPC H01L 25/048; F21S 2/005; H01L 51/5246; H01L 51/0096; H01L 51/5253; H01L 51/5203; F21Y 2115/20

(57) ABSTRACT

A plurality of transmissive organic EL panels in a light emitting device each include: a first transparent substrate; a second transparent substrate; an organic EL element; a resin sealant; a group of first terminals; and a group of second terminals. The group of first terminals and the group of second terminals are alternately arranged in a direction along an outer perimeter of the first transparent substrate. The plurality of transmissive organic EL panels are arranged in a two-dimensional array. In adjacent transmissive organic EL panels, the group of first terminals and the group of second terminals are inversely arranged. A first terminal among the group of first terminals of one of the adjacent transmissive organic EL panels and an overlapping second terminal among the group of second terminals of the other of the adjacent transmissive organic EL panels are electrically connected via a connector.

### TECHNICAL FIELD

The present invention relates to a light emitting device, and in particular, to a light emitting device including a plurality of transmissive organic EL panels.

### BACKGROUND ART

Conventionally, a lighting device has been proposed in which three organic light emitting elements are aligned in the right-and-left direction (Patent Literature (PTL) 1).

The organic light emitting elements each include one substrate. In each organic light emitting element, contact regions are formed on the surfaces on both sides of the substrate. Each contact region is connected to a first electrode and a second electrode below an encapsulated section. The three organic light emitting elements are arranged such that the contact regions thereof overlap. The contact regions of adjacent organic light emitting elements are connected together via an electrical contact.

With the lighting device, the overlap of the contact regions reduces the width of non-light-emitting regions and improves the ratio of the surface area of the light emitting surface to the entire surface area of the lighting device.

### CITATION LIST

### Patent Literature

PTL 1: Japanese Unexamined Patent Application Publication No. 2009-88515

### SUMMARY OF THE INVENTION

### Technical Problem

With the lighting device described above, three organic light emitting elements are arranged in a one-dimensional array, but there is no disclosure with regard to a structure for arranging the organic light emitting elements in a two-dimensional array.

An object of the present invention is to provide a light emitting device whose design can be improved while at the same time increasing surface area.

### Solutions to Problem

A light emitting device according to the present invention includes a plurality of transmissive organic (electroluminescent) EL panels. The plurality of transmissive organic EL panels each include: a first transparent substrate; a second transparent substrate; an organic EL element having a stacked structure configured of a first electrode, a light emitting function layer, and a second electrode; a resin sealant; a group of first terminals; and a group of second terminals. The first transparent substrate is formed in a rectangular shape. The second transparent substrate is formed in a rectangular shape and faces the first transparent substrate. The resin sealant covers the organic EL element, between the second transparent substrate and the first transparent substrate. The group of first terminals is disposed on the first transparent substrate in a peripheral region of the first transparent substrate, and electrically connected to the first electrode. The group of second terminals is disposed on the first transparent substrate in a peripheral region of the first transparent substrate, and electrically connected to the second electrode. The second transparent substrate is smaller than the first transparent substrate so as to expose the group of first terminals and the group of second terminals. The group of first terminals and the group of second terminals of each of the plurality of transmissive organic EL panels are alternately arranged in a direction along each outer perimeter edge of the first transparent substrate. The plurality of transmissive organic EL panels are arranged in a two-dimensional array. In adjacent transmissive organic EL panels among the plurality of transmissive organic EL panels, the group of first terminals and the group of second terminals are inversely arranged, the first transparent substrates overlap one another along one edge along the outer perimeter, and a first terminal among the group of first terminals of one of the adjacent transmissive organic EL panels and an overlapping second terminal among the group of second terminals of the other of the adjacent transmissive organic EL panels are electrically connected via a connector.

A light emitting device according to the present invention includes a plurality of transmissive organic (electroluminescent) EL panels. The plurality of transmissive organic EL panels each include: a first transparent substrate; a second transparent substrate; an organic EL element having a stacked structure configured of a first electrode, a light emitting function layer, and a second electrode; a resin sealant; a group of first terminals; and a group of second terminals. The first transparent substrate is formed in a rectangular shape. The second transparent substrate is formed in a rectangular shape and faces the first transparent substrate. The resin sealant covers the organic EL element, between the second transparent substrate and the first transparent substrate. The group of first terminals is disposed on the first transparent substrate in a peripheral region of the first transparent substrate, and electrically connected to the first electrode. The group of second terminals is disposed on the first transparent substrate in a peripheral region of the first transparent substrate, and electrically connected to the second electrode. The second transparent substrate is smaller than the first transparent substrate so as to expose the group of first terminals and the group of second terminals. The group of first terminals and the group of second terminals of each of the plurality of transmissive organic EL panels are alternately arranged in a direction along each outer perimeter edge of the first transparent substrate. The plurality of transmissive organic EL panels are arranged in a two-dimensional array. In adjacent transmissive organic EL panels among the plurality of transmissive organic EL panels, the group of first terminals and the group of second terminals are arranged in a same manner, the first transparent substrates overlap one another along one edge along the outer perimeter, a first terminal among the group of first terminals of one of the adjacent transmissive organic EL panels and an overlapping first terminal among the group of first terminals of the other of the adjacent transmissive organic EL panels are electrically connected via a connector, and a second terminal among the group of second terminals of one of the adjacent transmissive organic EL panels and an overlapping second terminal among the group of second terminals of the other of the adjacent transmissive organic EL panels are electrically connected via a connector.

### Advantageous Effect of Invention

With the light emitting device according to the present invention, design can be improved while at the same time increasing surface area.

### BRIEF DESCRIPTION OF DRAWINGS

FIG. 1 is a diagrammatic plan view of the light emitting device according to Embodiment 1.

FIG. 2 is a diagrammatic plan view of relevant portions of the light emitting device according to Embodiment 1.

FIG. 3 is a diagrammatic cross section view of relevant portions of the light emitting device according to Embodiment 1.

FIG. 4A is a diagrammatic plan view of the first transparent organic EL panel in the light emitting device according to Embodiment 1.

FIG. 4B is a diagrammatic plan view of the second transparent organic EL panel in the light emitting device according to Embodiment 1.

FIG. 5 is a diagrammatic plan view of the light emitting device according to Embodiment 2.

FIG. 6A is a diagrammatic cross section view of relevant portions of the light emitting device according to Embodiment 3.

FIG. 6B is a different diagrammatic cross section view of relevant portions of the light emitting device according to Embodiment 3.

### DESCRIPTION OF EXEMPLARY EMBODIMENT(S)

### Embodiment

The figures to be described in the following Embodiments 1 through 3 are schematic figures, and the ratio of the size and thickness of the elements are not necessarily true to actual dimensional ratios. Moreover, the materials and numerical values, for example, described in Embodiments 1 through 3 are indicative of preferred examples, and are not intended to be limiting. Further, the configuration of the present invention may be changed within the scope of the technical concept of the present invention.

### Embodiment 1

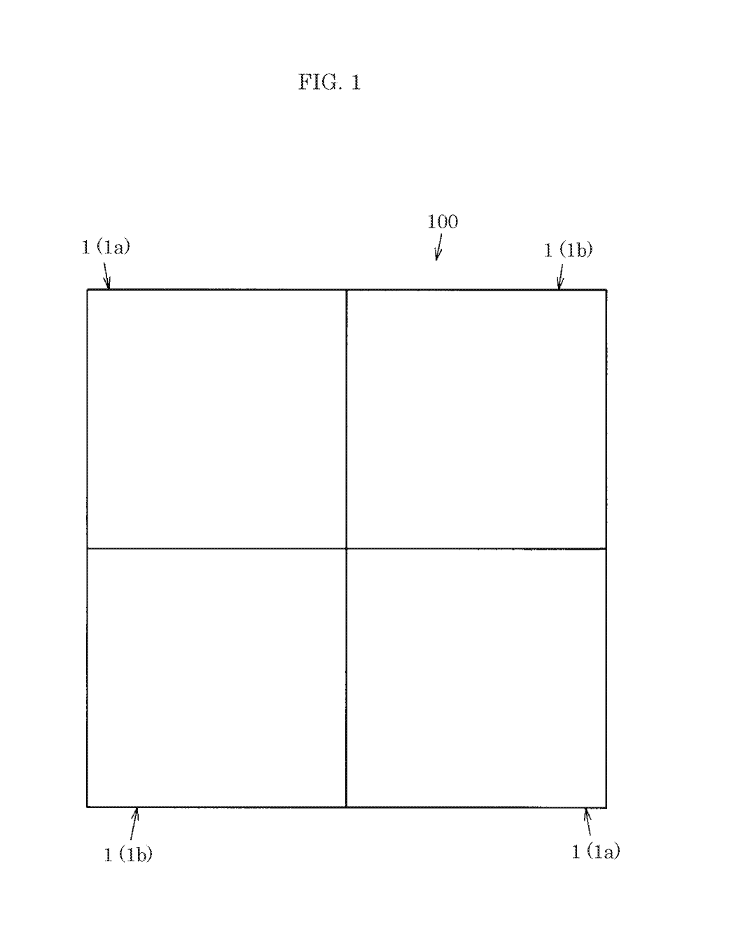

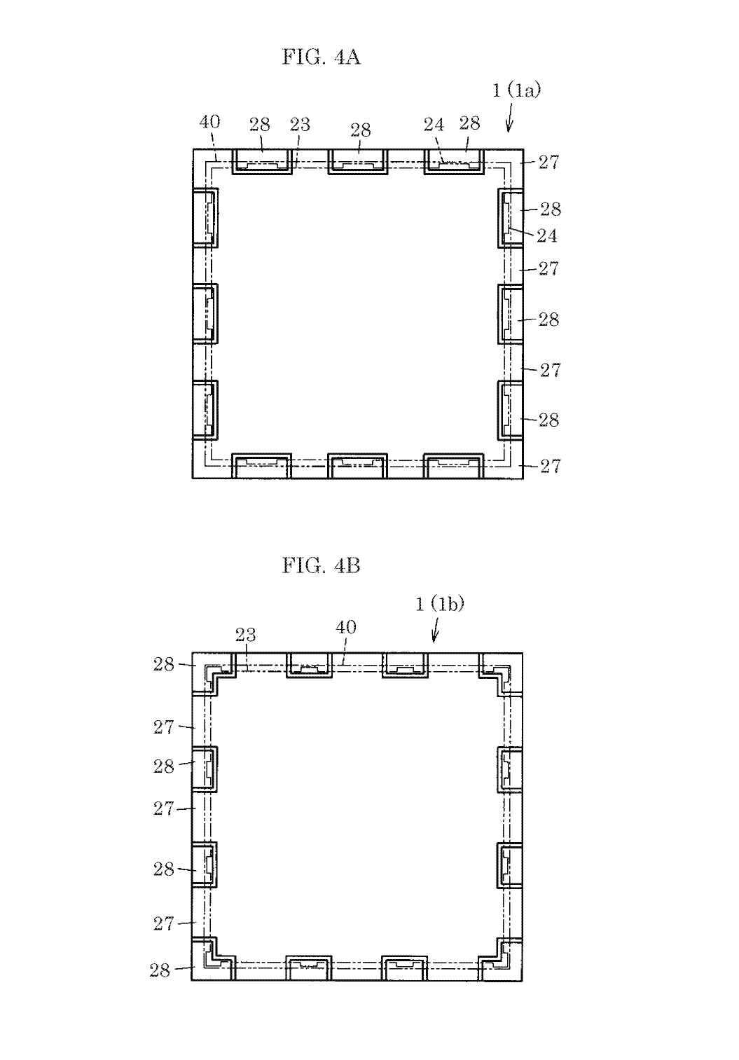

Light emitting device 100 according to this embodiment will be described based on FIG. 1 through FIG. 3, FIG. 4A, and FIG. 4B.

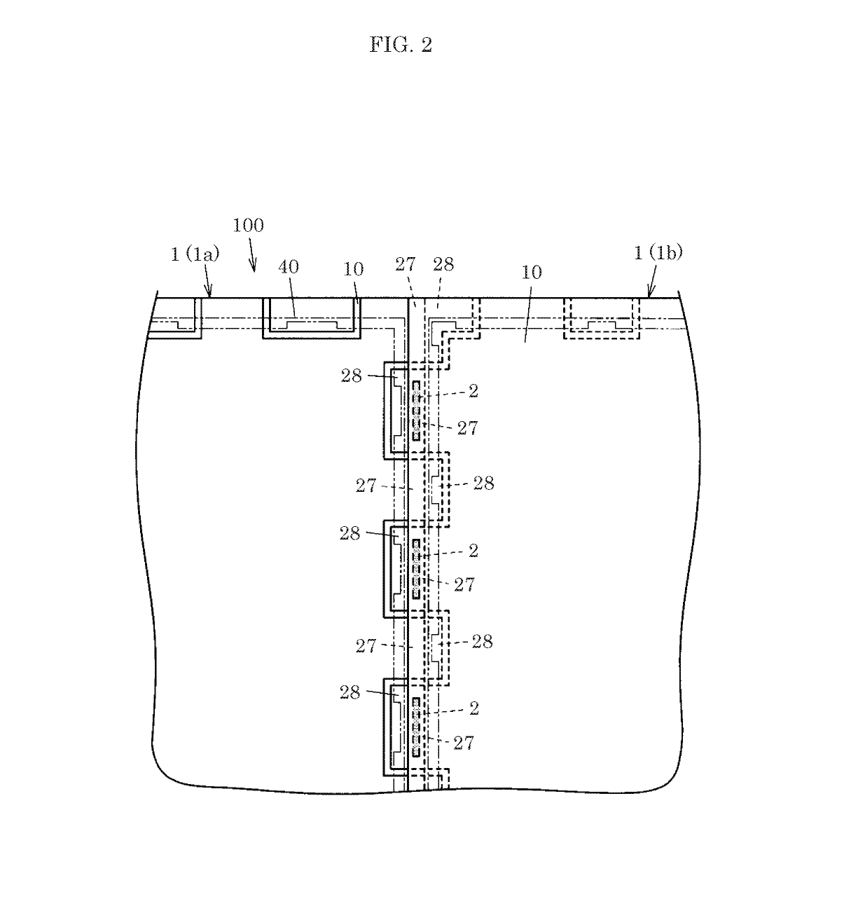

Light emitting device 100 includes a plurality of transmissive organic EL panels 1. Each of the plurality of transmissive organic EL panels 1 includes first transparent substrate 10, second transparent substrate 40, organic EL element 20, resin sealant 30, group of first terminals 27, and group of second terminals 28. Organic EL element 20 has a stacked structure configured of first electrode 21, light emitting function layer 22, and second electrode 23. First transparent substrate 10 is formed in a rectangular shape. Second transparent substrate 40 is formed in a rectangular shape and faces first transparent substrate 10. Resin sealant 30 covers organic EL element 20, between second transparent substrate 40 and first transparent substrate 10. Group of first terminals 27 is disposed on first transparent substrate 10 in a peripheral region of first transparent substrate 10, and electrically connected to first electrode 21. Group of second terminals 28 is disposed on first transparent substrate 10 in a peripheral region of first transparent substrate 10, and electrically connected to second electrode 23. Second transparent substrate 40 is smaller than first transparent substrate 10 so as to expose group of first terminals 27 and group of second terminals 28. Group of first terminals 27 and group of second terminals 28 of each of the plurality of transmissive organic EL panels 1 are alternately arranged in a direction along each outer perimeter edge of first transparent substrate 10. The plurality of transmissive organic EL panels 1 are arranged in a two-dimensional array. In adjacent transmissive organic EL panels 1, group of first terminals 27 and group of second terminals 28 are inversely arranged, and first transparent substrates 10 overlap one another along one edge along the outer perimeter. In adjacent transmissive organic EL panels 1, a first terminal 27 among group of first terminals 27 of one of the adjacent transmissive organic EL panels 1 and an overlapping second terminal 28 among group of second terminals 28 of the other of the adjacent transmissive organic EL panels 1 are electrically connected via connector 2. The design of the above light emitting device 100 can be improved while at the same time increasing surface area. Note that in FIG. 2, FIG. 4A, and FIG. 4B, in order to illustrate, in an easy to understand manner, the positions in which group of first terminals 27 and group of second terminals 28 are arranged, second electrode 23 and second transparent substrate 40 are each outlined with a double-dashed line.

Each element in light emitting device 100 will hereinafter be described in detail.

Transmissive organic EL panel 1 is an organic EL panel capable of emitting light from both sides intersecting the thickness direction. In other words, the transmissive organic EL panel is a double-sided light emitting panel.

For example, a glass substrate can be used as first transparent substrate 10. For example, a glass substrate can be used as second transparent substrate 40. In transmissive organic EL panel 1, first transparent substrate 10 and second transparent substrate 40 are preferably made of the same material. Moreover, in transmissive organic EL panel 1, first transparent substrate 10 and second transparent substrate 40 preferably have little difference in regard to their linear expansion coefficients, and even more preferably have the same linear expansion coefficient. With this, in transmissive organic EL panel 1, stress due to first transparent substrate 10 and second transparent substrate 40 having different linear expansion coefficients can be reduced.

Glass substrates are used for first transparent substrate 10 and second transparent substrate 40, but first transparent substrate 10 and second transparent substrate 40 are not limited to glass substrates; for example, plastic substrates may be used. For example, a soda-lime glass substrate or an alkali-free glass substrate can be used as the glass substrate. Further, a polyethylene terephthalate (PET) substrate, a polyethylene naphthalate (PEN) substrate, a polyethersulfone (PES) substrate, or a polycarbonate (PC) substrate may be used as the plastic substrate.

When a glass substrate is used as first transparent substrate 10, the roughness of surface 11 of first transparent substrate 10 that faces second transparent substrate 40 may lead to generation of, for example, leak current with respect to organic EL element 20. As such, when a glass substrate is used for first transparent substrate 10, it is preferable that a glass substrate for forming elements that has been highly accurately polished to remove any roughness from surface 11 be used. Regarding the roughness of surface 11 of first transparent substrate 10, for example, surface 11 preferably has an arithmetic mean roughness Ra as stipulated in JIS B 0601-2001 (ISO 4287-1997) that is a few nanometers or less. In contrast, when a plastic substrate is used as first transparent substrate 10, surface 11 having an arithmetic mean roughness Ra that is a few nanometers or less can be formed at low cost, without particularly having to highly accurately polish surface 11.

First transparent substrate 10 is formed so as to have a rectangular (quadrilateral shape where every angle is a right angle) outline. Transmissive organic EL panel 1 is preferably arranged such that a central line along the thickness direction of first transparent substrate 10 is aligned with a central line along the thickness direction of second transparent substrate 40. In transmissive organic EL panel 1, it is preferably that the size of second transparent substrate 40 be set such that the peripheral region of first transparent substrate 10 that does not overlap with second transparent substrate 40 has a constant width. In transmissive organic EL panel 1, when first transparent substrate 10 has a square outline, second transparent substrate 40 preferably also has a square outline.

Organic EL element 20 is a transmissive organic EL element capable of emitting light from both sides intersecting the thickness direction.

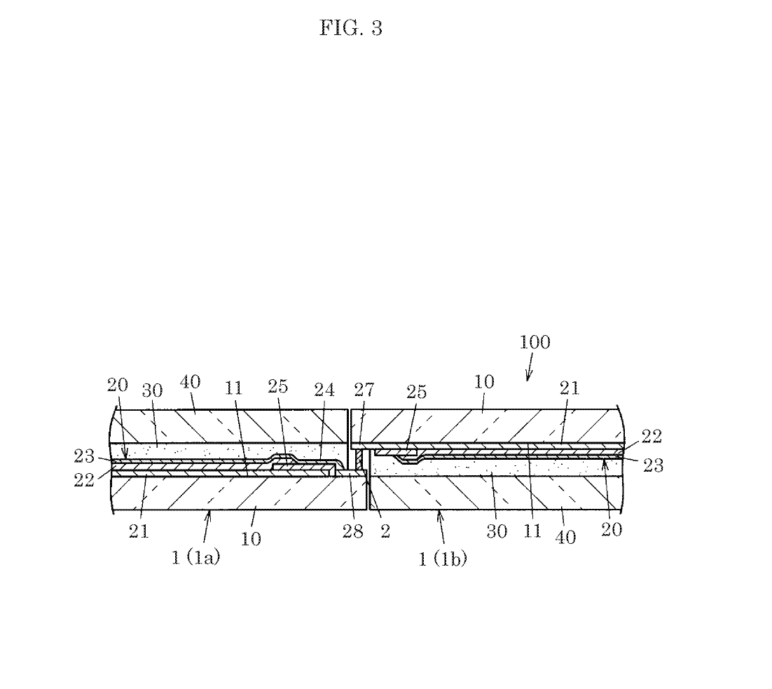

As illustrated in FIG. 3, in organic EL element 20, first electrode 21 and second electrode 23 are disposed spaced from each other in a direction along the thickness direction of first transparent substrate 10, and light emitting function layer 22 is disposed between first electrode 21 and second electrode 23.

First electrode 21 preferably has a rectangular outline. First electrode 21 is both electrically conductive and light transmissive. For example, first electrode 21 is preferably formed of a transparent conducting oxide. Examples of the transparent conducting oxide include ITO, AZO, and GZO.

Second electrode 23 preferably has a rectangular outline. Second electrode 23 is both electrically conductive and light transmissive. For example, a resin containing electrically conductive particles or a transparent conducting oxide may be used as the material for second electrode 23. For example, electrically conductive nanostructures can be used as the electrically conductive particles. For example, electrically conductive nanoparticles or electrically conductive nanowires can be used as the electrically conductive nanostructures. The particle diameter of the electrically conductive nanoparticles is preferably in a range from 1 to 100 nanometers. Further, the diameter of the electrically conductive nanowires is preferably in a range from 1 to 100 nanometers. For example, silver, gold, ITO, and IZO can be used as the material for the electrically conductive nanostructures. Examples of the resin include, but are not limited to, acrylic, polyethylene, polypropylene, polyethylene terephthalate, polymethyl methacrylate, polystyrene, polyethersulfone, polyarylate, polycarbonate, polyurethane, polyacrylonitrile, polyvinyl acetal, polyamide, polyimide, diallyl phthalate, cellulose resin, polyvinyl chloride, polyvinylidene chloride, polyvinyl acetate, other thermoplastic resins, and copolymers including two or more monomers of the above resins. For example, an electrically conductive polymer such as polythiophene, polyaniline, polypyrrol, polyphenylene, polyphenylene vinylene, polyacetylene, polycarbazole is preferably used as the resin. These may be used as individually or as a combination. Moreover, second electrode 23 may have a stacked structure configured of a transparent conducting oxide layer and a 10 nm thick or less metal layer.

First electrode 21 and second electrode 23 preferably have a visible light transmittance of 60% or more relative to total transmittance, more preferably 70% or more, and even more preferably 80% or more. Note the method used to measure total transmittance may be a method stipulated in ISO 13468-1.

Moreover, second electrode 23 may be configured of a first electrode layer that is a transparent electrode layer, and a second electrode layer formed in a mesh pattern from a material more electrically conductive than the transparent electrode layer. The holes of the mesh second electrode layer may be opened. The second electrode layer is not limited to a mesh pattern, and may be formed in a comb-like shape. The transparent electrode layer can be made from a resin containing electrically conductive particles, for example. The second electrode layer can be formed using a silver paste, for example.

In organic EL element 20, first electrode 21 is the anode, and second electrode 23 is the cathode. Light emitting function layer 22 of organic EL element 20 includes, in order from closest to first electrode 21, a hole transport layer, a light emitting layer, an electron transport layer, and an electron injection layer. In organic EL element 20, first electrode 21 may be the cathode, and second electrode 23 may be the anode.

The stacked structure of light emitting function layer 22 is not limited to the example given above. For example, light emitting function layer 22 may have a single layer structure of the light emitting layer, a stacked structure configured of the hole transport layer, the light emitting layer, and the electron transport layer, a stacked structure configured of the hole transport layer and the light emitting layer, or a stacked structure configured of the light emitting layer and the electron transport layer. Moreover, light emitting function layer 22 may include a hole injection layer disposed between first electrode 21 and the hole transport layer. Further, the light emitting layer may have a single or multi-layer structure. When the desired light emission color is white, the light emitting layer in light emitting function layer 22 may be doped with three pigments of dopants—red, green, and blue—may have a stacked structure configured of a blue color positive hole transport light emitting layer, a green color electron transport light emitting layer, and red color electron transport light emitting layer, and may have a stacked structure configured of a blue color electron transport light emitting layer, a green color electron transport light emitting layer, and a red color electron transport light emitting layer.

First electrode 21, which is the anode, is an electrode for injecting holes into the light emitting layer. First electrode 21, which is the anode, is preferably made of a material having a work function in a range from 4 eV to 6 eV so as to keep the difference between the work function and the HOMO (highest occupied molecular orbital) level from being too large.

Second electrode 23, which is the cathode, is an electrode for injecting electrons into the light emitting layer. Second electrode 23, which is the cathode, is preferably made of a material having a work function in a range from 1.9 eV to 5 eV so as to keep the difference between the work function and the LUMO (lowest unoccupied molecular orbital) level from being too large.

Examples of the material for the light emitting layer include, but are not limited to, anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bistyryl, cyclopentadiene, quinoline metal complex, tris(8-hydroxyquinolinate)aluminum complex, tris(4-methyl-8-quinolinate)aluminum complex, tris(5-phenyl-8-quinolinate)aluminum complex, aminoquinoline metal complex, benzoquinoline metal complex, tri(p-tarphenyl-4-il)amine, 1-allyl-2,5-di(2-thienyl)pyrrole derivative, pyran, quinacridone, rubrene, distyrylbenzene derivative, distrylarylene derivative, distrylamine derivative, and various fluorescent dyes. Further, the material used for the light emitting layer may be a material indicating light emission from the spin multiplet. Examples of this type of material include a light emitting phosphorescent material that emits phosphorescence.

Examples of the material for the hole injection layer include an organic material having hole injection properties, a metal oxide having hole injection properties, and an acceptor organic material. Organic materials having hole injection properties are materials having hole injection properties. Examples of these kinds of materials include CuPc and starburst amine. Examples of metal oxides having hole injection properties include a metal oxide containing at least one of molybdenum, rhenium, tungsten, vanadium, zinc, indium, tin, gallium, titanium, and aluminum.

Examples of the material for the hole transport layer include those selected from a group of chemical compounds having hole transport properties. Representative examples of this type of chemical compound include 4,4′-bis[N-(naphthyl)-N-phenyl-amino]biphenyl(α-NPD), N,N′-bis(3-methylphenyl)-(1,1′-biphenyl)-4,4′-diamine(TPD), 2-TNATA, 4,4′,4″-tris(N-(3-methylphenyl)N-phenylamino)triphenylamine(MTDATA), 4,4′-N,N′-dicarbazolbiphenyl(CBP), spiro-NPD, spiro-TPD, spiro-TAD, TNB, and other examples include allyl amine compounds, anime compounds including carbazole as a base, amine compounds including fluorine derivatives.

Examples of the material for the electron transport layer include those selected from a group of chemical compounds having electron transport properties. Examples of such chemical compounds include: a metal complex known for being an electron transport material, such as Alq3; and chemical compounds including a hetero ring, such as a phenanthroline derivative, a pyridine derivative, a tetrazine derivative, and an oxadiazole derivative.

Examples of the material for the electron injection layer include: metal fluorides such as lithium fluoride and magnesium fluoride; metal halides such as metal chlorides of which representative examples include sodium chloride and magnesium chloride; oxides, nitrides, carbides, and oxynitrides of various metals such as aluminum, cobalt, zirconium, titanium, vanadium, niobium, chromium, tantalum, tungsten, manganese, molybdenum, ruthenium, iron, nickel, copper, gallium, zinc, and silicon; insulators such as aluminum oxide, magnesium oxide, iron oxide, aluminum nitride, silicon nitride, silicon carbide, silicon oxynitride, and boron nitride; and silicon or carbon compounds such as SiO2 and SiO.

Moreover, the material for the electron injection layer may be mixed material consisting of one type of an organic material having electron transport properties mixed with an alkali metal, and alkali earth metal, magnesium, samarium, or yytriun Examples of an alkali metal include lithium, sodium, potassium, rubidium, and cesium. Examples of an alkali earth metal include calcium, strontium, and barium. Moreover, the material for the electron injection layer may be mixed material consisting of one type of an organic material having electron transport properties mixed with an oxide of a rare-earth metal, a fluoride of a rare-earth metal, a chloride of a rare-earth metal, or a halide of a rare-earth metal.

Group of first terminals 27 and group of second terminals 28 are preferably formed of a transparent conducting oxide, for example. Group of first terminals 27 and group of second terminals 28 are, in one preferable embodiment, configured to have a stacked structure configured of a thin metal film having a thickness of approximately a few nanometers and a transparent conducting oxide film, and more preferably has a stacked structure configured of a thin metal film having a thickness of a few nanometers above a transparent conducting oxide film. Group of first terminals 27 and group of second terminals 28 are preferably formed of the same material as first electrode 21. With this, when manufacturing transmissive organic EL panel 1, for example, after forming a transparent conducting oxide film on the entire surface 11 of first transparent substrate 10, first electrode 21, group of first terminals 27, and group of second terminals 28 can be formed by patterning the transparent conducting oxide film.

Second electrode 23 is electrically connected to second terminal 28 via lead wire 24 that extends integrally from second electrode 23. The same material used for second electrode 23 may be used for lead wire 24. The same material used for second electrode 23 may be used for lead wire 24. Therefore, when manufacturing light emitting device 100, it is possible to form lead wire 24 and second electrode 23 at the same time. The width of lead wire 24 is preferably slightly narrower than the width of second terminal 28.

Organic EL element 20 includes electrical insulation film 25 that covers the peripheral region of first electrode 21 on surface 11 side of first transparent substrate 10. Electrical insulation film 25 is provided to prevent first electrode 21 and lead wire 24 from short circuiting. Electrical insulation film 25 has a rectangular frame-like shape in a plan view.

Polyimide is used for the material for electrical insulation film 25, but the material used is not limited to this example; other examples include novolak resin, epoxy resin, and acrylic resin.

Organic EL element 20 may include an auxiliary electrode (not illustrated in the drawings) electrically connected to first electrode 21. The auxiliary electrode is made of a material having a lower resistivity than first electrode 21. Preferable examples of the material for the auxiliary electrode include metals such as aluminum, silver, gold, copper, chromium, molybdenum, aluminum, palladium, tin, lead, and magnesium, and composite metals including at least one of the aforementioned metals. Moreover, the auxiliary electrode is not limited to a single layer structure; the auxiliary electrode may have a multilayer structure. For example, the auxiliary electrode may have a three-layer structure configured of a MoNb layer, an AlNd layer, and a MoNb layer. In this three-layer structure, it is preferable that the lower MoNb layer is provided as an adhesive layer for the base material, and the upper MoNb layer is provided as a protection layer for the AlNd layer. Moreover, the auxiliary electrode is formed along the peripheral region of the surface of first electrode 21 opposite the first transparent substrate 10 side surface. When organic EL element 20 includes an auxiliary electrode, electrical insulation film 25 is preferably formed so as to cover the peripheral region of the auxiliary electrode and first electrode 21, on the surface 11 side of first transparent substrate 10.

Note that the light emission color of organic EL element 20 may be, for example, white, and may be blue, green or red. Moreover, the light emission color of organic EL element 20 may be an intermediate color between blue and green or between green and red.

The outline of resin sealant 30 is preferably the same rectangular shape as second transparent substrate 40. Resin sealant 30 covers, for example, second electrode 23, electrical insulation film 25, and lead wire 24.

Examples of the material used for resin sealant 30 include imide type resin, silicon resin, epoxy resin, polyimide resin, acrylic resin, and styrene resin.

In transmissive organic EL panel 1, the region in which first transparent substrate 10, first electrode 21, light emitting function layer 22, second electrode 23, resin sealant 30, and second transparent substrate 40 overlap in the thickness direction of first transparent substrate 10 forms the light emitting unit, and the region other than the light emitting unit is a non-light-emitting unit. In organic EL element 20 of transmissive organic EL panel 1, the rectangular outlines of first electrode 21, light emitting function layer 22, and second electrode 23 are smaller than the rectangular outlines of first transparent substrate 10 and second transparent substrate 40. Therefore, the light emitting unit of transmissive organic EL panel 1 has a smaller rectangular outline than that of first transparent substrate 10 and second transparent substrate 40.

As described above, group of first terminals 27 and group of second terminals 28 of transmissive organic EL panel 1 are alternately arranged in a direction along each outer perimeter edge of first transparent substrate 10. Therefore, in transmissive organic EL panel 1, first terminal 27 and second terminal 28 are alternately arranged in a direction along the outer perimeter of first transparent substrate 10, and first terminal 27 and second terminal 28 are alternately arranged in a direction along each outer perimeter edge of first transparent substrate 10.

The plurality of transmissive organic EL panels 1 includes first transmissive organic EL panel 1a on which group of first terminals 27 and group of second terminals 28 are arranged such that first terminal 27 is located at each corner of first transparent substrate 10, and second transmissive organic EL panel 1b on which group of first terminals 27 and group of second terminals 28 are arranged such that second terminal 28 is located at each corner of first transparent substrate 10. In other words, between first transmissive organic EL panel 1a and second transmissive organic EL panel 1b, group of first terminals 27 and group of second terminals 28 are inversely arranged.

In light emitting device 100, first transmissive organic EL panel 1a and second transmissive organic EL panel 1b are arranged to be adjacent one another, and mutual first transparent substrates 10 overlap one another along one outer perimeter edge. More specifically, in the examples illustrated in FIG. 2 and FIG. 3, the right edge of first transparent substrate 10 in first transmissive organic EL panel 1a on the left and the left edge of first transparent substrate 10 in second transmissive organic EL panel 1b on the right overlap one another with a space therebetween. The distance between first transparent substrate 10 of first transmissive organic EL panel 1a and first transparent substrate 10 of second transmissive organic EL panel 1b is preferably approximately equal to the total thickness of organic EL element 20 and resin sealant 30. With this, in light emitting device 100, the light extracting surface of second transparent substrate 40 in first transmissive organic EL panel 1a and the light extracting surface of first transparent substrate 10 in second transmissive organic EL panel 1a can be made to be substantially flush. Moreover, in light emitting device 100, the light extracting surface of first transparent substrate 10 in first transmissive organic EL panel 1a and the light extracting surface of second transparent substrate 40 in second transmissive organic EL panel 1a can be made to be substantially flush.

In adjacent transmissive organic EL panels 1 among the plurality of transmissive organic EL panels 1, second terminal 28 of first transmissive organic EL panel 1a and first terminal 27 of second transmissive organic EL panel 1b are electrically connected via connector 2.

The distance between first transparent substrate 10 of first transmissive organic EL panel 1a and first transparent substrate 10 of second transmissive organic EL panel 1b is determined according to the thickness of connector 2. Moreover, the narrower the width of connector 2 in the direction in which adjacent first transmissive organic EL panel 1a and second transmissive organic EL panel 1b are aligned is, the more the surface area of the non-light-emitting region of light emitting device 100 can be reduced and the more the surface area of the light emitting region of light emitting device 100 can be increased. Therefore, the design of light emitting device 100 can be improved while at the same time increasing surface area.

With respect to each of the plurality of transmissive organic EL panels 1, a lighting state of light emitting from the first transparent substrate 10 side and a lighting state of light emitting from the second transparent substrate 40 side are preferably the same state. Examples of lighting states include color and luminance. Thus, in light emitting device 100, it is possible to reduce unevenness in color or luminance between the two sides. The lighting state of light emitting from the first transparent substrate 10 side and the lighting state of light emitting from the second transparent substrate 40 side can be made to be the same state through the element design of organic EL element 20 and the design of resin sealant 30. Here, the term “same” is not limited to exactly the same, and includes substantially the same, so as to account for slight margins of error, for example. The element design of organic EL element 20 means the design choices in regard to, for example, the material used for and thickness of first electrode 21, light emitting function layer 22, and second electrode 23. Moreover, the design of resin sealant 30 means the design choices in regard to, for example, the material used for and thickness of resin sealant 30.

Connector 2 is preferably formed in a line along one edge of first transparent substrate 10. With this, in light emitting device 100, the width of the non-light-emitting region can be further reduced, and the design of light emitting device 100 can be improved.

Connector 2 has a width of 20 micrometers or less in a direction perpendicular to one edge of first transparent substrate 10. With this, in light emitting device 100, it is possible to make the width of the overlapping portion of adjacent transmissive organic EL panels 1 one millimeter or less.

Connector 2 is preferably formed of a metal layer. The metal layer is preferably formed of sintered silver. This is a stacked structure of silver particles bonded together. More specifically, sintered silver is a sintered structure bonded by sintering silver particles together. In this case, connector 2 can be formed from an electrically conductive paste of coated silver nanoparticles, which are capable of being sintered at 120 degrees Celsius or lower, dispersed in a solvent. With this sort of coated silver nanoparticles, the protective film thereof can be removed even at a low temperature of 120 degrees Celsius or less, which makes sintering possible. Known coated silver nanoparticles include, for example, those protected with medium to short chain alkylamine and medium to short chain alkyldiamine. The average particle diameter of the coated silver nanoparticles is 30 nanometers or larger. When forming connector 2, after applying electrically conductive paste in a suitable location on one transmissive organic EL panel 1 among adjacent transmissive organic EL panels 1, the other transmissive organic EL panel 1 is superposed on the one transmissive organic EL panel 1, and then the electrically conductive paste can be heated to form connector 2.

The electrically conductive paste is preferably applied using, for example, a dispenser system. With this, connector 2 can be made to have a width from 20 micrometers to a few micrometers.

When applying the electrically conductive paste using the dispenser system, for example, the electrically conductive paste can be dispensed from the nozzle and applied while the dispenser head is moved along one edge of first transparent substrate 10 of first transmissive organic EL panel 1.

The dispenser system preferably includes a moving mechanism for moving the dispenser head, a sensor that measures the heights of surface 11 of first transparent substrate 10 and the nozzle from the table, and a controller that controls the moving mechanism and the amount of electrically conductive paste dispensed from the nozzle. The moving mechanism can be, for example, a robot. The controller can be, for example, realized by installing an appropriate program in a microcomputer. Moreover, by changing the program installed in the controller, the dispenser system can accommodate a variety of types, shapes, and widths of connector 2.

Connector 2 is not limited to being formed in a line along the one edge of first transparent substrate 10; connector 2 may be formed in a plurality of broken lines.

### Embodiment 2

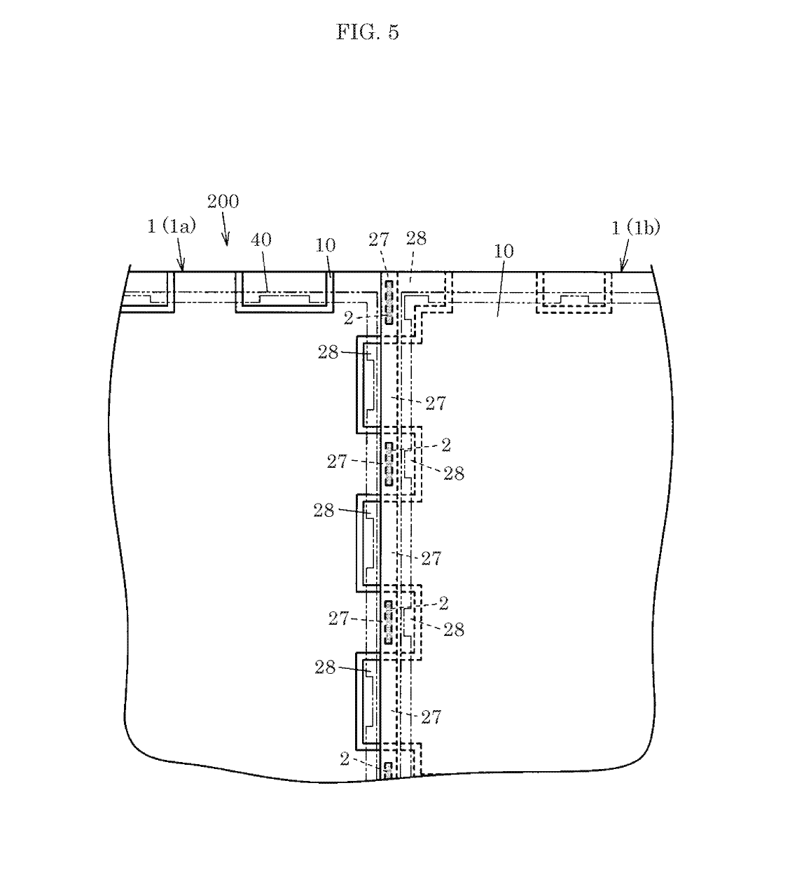

Hereinafter, light emitting device 200 according to this embodiment will be described based on FIG. 5.

Light emitting device 200 according to this embodiment differs from light emitting device 100 according to Embodiment 1 in regards to the arrangement of connector 2. Note that elements that are the same as in light emitting device 100 according to Embodiment 1 share the same reference marks, and as such, descriptions thereof are omitted.

In adjacent transmissive organic EL panels 1 among the plurality of transmissive organic EL panels 1 of light emitting device 200, first terminal 27 of first transmissive organic EL panel 1a and second terminal 28 of second transmissive organic EL panel 1b are electrically connected via connector 2. All other configurations of light emitting device 200 are the same as light emitting device 100. Therefore, the design of light emitting device 200 can be improved while at the same time increasing surface area.

### Embodiment 3

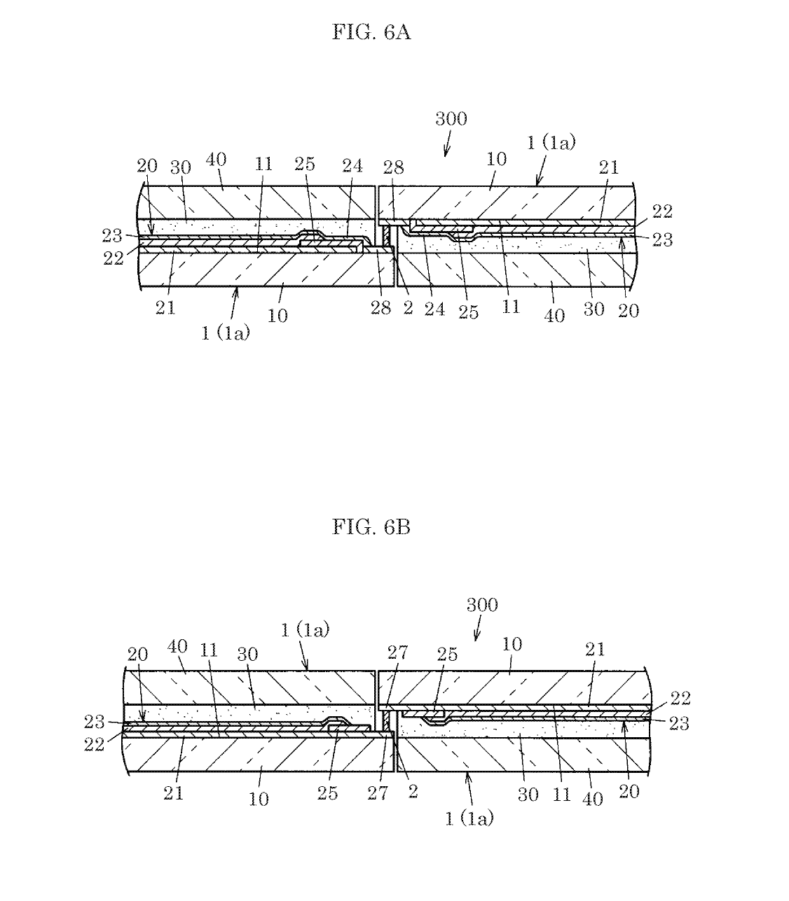

Hereinafter, light emitting device 300 according to this embodiment will be described based on FIG. 6A and FIG. 6B.

Light emitting device 300 according to this embodiment is substantially the same as light emitting device 100 according to Embodiment 1, but differs in that all of the plurality of transmissive organic EL panels 1 are first transmissive organic EL panels 1a, and first terminals 27 of adjacent transmissive organic EL panels 1 are electrically connected to each other via connector 2, and second terminals 28 of adjacent transmissive organic EL panels 1 are electrically connected to each other via connector 2. Note that elements that are the same as in light emitting device 100 according to Embodiment 1 share the same reference marks, and as such, descriptions thereof are omitted.

Light emitting device 300 according to this embodiment includes a plurality of transmissive organic EL panels 1. Each of the plurality of transmissive organic EL panels 1 includes first transparent substrate 10, second transparent substrate 40, organic EL element 20, resin sealant 30, group of first terminals 27, and group of second terminals 28. Organic EL element 20 has a stacked structure configured of first electrode 21, light emitting function layer 22, and second electrode 23. First transparent substrate 10 is formed in a rectangular shape. Second transparent substrate 40 is formed in a rectangular shape and faces first transparent substrate 10. Resin sealant 30 covers organic EL element 20, between second transparent substrate 40 and first transparent substrate 10. Group of first terminals 27 is disposed on first transparent substrate 10 in a peripheral region of first transparent substrate 10, and electrically connected to first electrode 21. Group of second terminals 28 is disposed on first transparent substrate 10 in a peripheral region of first transparent substrate 10, and electrically connected to second electrode 23. Second transparent substrate 40 is smaller than first transparent substrate 10 so as to expose group of first terminals 27 and group of second terminals 28. Group of first terminals 27 and group of second terminals 28 of each of the plurality of transmissive organic EL panels 1 are alternately arranged in a direction along each outer perimeter edge of first transparent substrate 10. The plurality of transmissive organic EL panels 1 are arranged in a two-dimensional array. In adjacent transmissive organic EL panels 1, group of first terminals 27 and group of second terminals 28 arranged in the same manner, and first transparent substrates 10 overlap one another along one edge along the outer perimeter. In adjacent transmissive organic EL panels 1, a first terminal 27 among group of first terminals 27 of one of the adjacent transmissive organic EL panels 1 and an overlapping first terminal 27 among group of first terminals 27 of the other of the adjacent transmissive organic EL panels 1 are electrically connected via connector 2. In adjacent transmissive organic EL panels 1, a second terminal 28 among group of second terminals 28 of one of the adjacent transmissive organic EL panels 1 and an overlapping second terminal 28 among group of second terminals 28 of the other of the adjacent transmissive organic EL panels 1 are electrically connected via connector 2. Therefore, the design of light emitting device 200 can be improved while at the same time increasing surface area.

### REFERENCE MARKS IN THE DRAWINGS

1 transmissive organic EL panel
1a first transmissive organic EL panel
1b second transmissive organic EL panel
2 connector
10 first transparent substrate
20 organic EL element
21 first electrode
22 light emitting function layer
23 second electrode
27 first terminal
28 second terminal
40 second transparent substrate
100 light emitting device
200 light emitting device
300 light emitting device

1. A light emitting device, comprising:
a plurality of transmissive organic electroluminescent (EL) panels,
wherein the plurality of transmissive organic EL panels each include: a first transparent substrate; a second transparent substrate; an organic EL element having a stacked structure configured of a first electrode, a light emitting function layer, and a second electrode; a resin sealant; a group of first terminals; and a group of second terminals,
the first transparent substrate is formed in a rectangular shape,
the second transparent substrate is formed in a rectangular shape and faces the first transparent substrate,
the resin sealant covers the organic EL element, between the second transparent substrate and the first transparent substrate,
the group of first terminals is disposed on the first transparent substrate in a peripheral region of the first transparent substrate, and electrically connected to the first electrode,
the group of second terminals is disposed on the first transparent substrate in a peripheral region of the first transparent substrate, and electrically connected to the second electrode,
the second transparent substrate is smaller than the first transparent substrate so as to expose the group of first terminals and the group of second terminals,
the group of first terminals and the group of second terminals of each of the plurality of transmissive organic EL panels are alternately arranged in a direction along each outer perimeter edge of the first transparent substrate,
the plurality of transmissive organic EL panels are arranged in a two-dimensional array, and
in adjacent transmissive organic EL panels among the plurality of transmissive organic EL panels, the group of first terminals and the group of second terminals are inversely arranged, the first transparent substrates overlap one another along one edge along the outer perimeter, and a first terminal among the group of first terminals of one of the adjacent transmissive organic EL panels and an overlapping second terminal among the group of second terminals of the other of the adjacent transmissive organic EL panels are electrically connected via a connector.

2. A light emitting device, comprising:
a plurality of transmissive organic EL panels,
wherein the plurality of transmissive organic EL panels each include: a first transparent substrate; a second transparent substrate; an organic EL element having a stacked structure configured of a first electrode, a light emitting function layer, and a second electrode; a resin sealant; a group of first terminals; and a group of second terminals,
the first transparent substrate is formed in a rectangular shape,
the second transparent substrate is formed in a rectangular shape and faces the first transparent substrate,
the resin sealant covers the organic EL element, between the second transparent substrate and the first transparent substrate,
the group of first terminals is disposed on the first transparent substrate in a peripheral region of the first transparent substrate, and electrically connected to the first electrode,
the group of second terminals is disposed on the first transparent substrate in a peripheral region of the first transparent substrate, and electrically connected to the second electrode,
the second transparent substrate is smaller than the first transparent substrate so as to expose the group of first terminals and the group of second terminals,
the group of first terminals and the group of second terminals of each of the plurality of transmissive organic EL panels are alternately arranged in a direction along each outer perimeter edge of the first transparent substrate,
the plurality of transmissive organic EL panels are arranged in a two-dimensional array, and
in adjacent transmissive organic EL panels among the plurality of transmissive organic EL panels, the group of first terminals and the group of second terminals are arranged in a same manner, the first transparent substrates overlap one another along one edge along the outer perimeter, a first terminal among the group of first terminals of one of the adjacent transmissive organic EL panels and an overlapping first terminal among the group of first terminals of the other of the adjacent transmissive organic EL panels are electrically connected via a connector, and a second terminal among the group of second terminals of one of the adjacent transmissive organic EL panels and an overlapping second terminal among the group of second terminals of the other of the adjacent transmissive organic EL panels are electrically connected via a connector.

3. The light emitting device according to claim 1, wherein
in the plurality of transmissive organic EL panels, a lighting state of light emitting from a first transparent substrate side and a lighting state of light emitting from a second transparent substrate side are a same state.

4. The light emitting device according to claim 1, wherein
the connector is formed in a line along the one edge.

5. The light emitting device according to claim 4, wherein
the connector has a width of 20 micrometers or less in a direction perpendicular to the one edge.

6. The light emitting device according to claim 2, wherein
in the plurality of transmissive organic EL panels, a lighting state of light emitting from a first transparent substrate side and a lighting state of light emitting from a second transparent substrate side are a same state.

7. The light emitting device according to claim 2, wherein
the connector is formed in a line along the one edge.

8. The light emitting device according to claim 7, wherein
the connector has a width of 20 micrometers or less in a direction perpendicular to the one edge.
